(19) United States
(12) Patent Application Publication
(10) Pub. No.: US 2026/0267547 A1
(43) Pub. Date: Sep. 10, 2026

(54) MEMORY TEST SYSTEM AND TEST METHOD THEREOF

(71) Applicant: Winbond Electronics Corp., Taichung City (TW)

(72) Inventors: Simon Chuan Hui Ong, Taichung City (TW); Shao-Ching Liao, Taichung City (TW)

(73) Assignee: Winbond Electronics Corp., Taichung City (TW)

(21) Appl. No.: 19/554,582

(22) Filed: Mar. 2, 2026

(30) Foreign Application Priority Data
Mar. 6, 2025 (TW) 114108379

(51) Int. Cl. G06F 3/06

(52) U.S. Cl. CPC G06F 3/0653; G06F 3/0604; G06F 3/0679

(57) ABSTRACT

A memory test system and a test method thereof are provided. The memory test system includes a memory array, a voltage control device, a test device, and a determination device. The voltage control device is configured to change states of a gate terminal pad, a drain terminal pad, a source terminal pad, and a bulk terminal pad during a period of performing a test operation. The test device is configured to provide multiple output signals according to changes in the states of the gate terminal pad, the drain terminal pad, the source terminal pad, and the bulk terminal pad. The determination device determines whether a breakdown phenomenon occurs in the memory array and a location where the breakdown phenomenon occurs according to the output signals.

### CROSS-REFERENCE TO RELATED APPLICATION

This application claims the priority benefit of Taiwan application serial no. 114108379, filed on Mar. 6, 2025. The entirety of the above-mentioned patent application is hereby incorporated by reference herein and made a part of this specification.

### BACKGROUND

### Technical Field

The disclosure relates to a test system, and more particularly to a memory test system and a test method adopted thereby.

### Description of Related Art

Cell isolation is a key indicator of reliability of a flash memory. Due to the miniaturization requirement of a process, the unit size is reduced, resulting in a reduction in the thickness of a sidewall oxide layer encapsulating a memory cell, which reduces the degree of voltage resistance of the sidewall oxide layer, thereby easily causing leakage, affecting reliability.

Currently, leakage caused by the breakdown of the sidewall oxide layer generally requires cutting a wafer to perform detection through a physical failure analysis (PFA), such as transmission electron microscopy (TEM) or energy dispersive X-ray spectroscopy (EDS). However, the analysis manner is not only time-consuming but also costly and is not suitable for mass production of products. Therefore, how to determine a region where a breakdown phenomenon occurs through a quick and concise electrical failure analysis (EFA), thereby improving the process, is one of the important topics in the art.

### SUMMARY

The disclosure provides a memory test system and a test method thereof, which can quickly detect a breakdown phenomenon in a memory array.

A memory test system of the disclosure includes a memory array, a voltage control device, a test device, and a determination device. The memory array has multiple word lines, multiple bit lines, and multiple source lines. The word lines are commonly coupled to a gate terminal pad, the bit lines are commonly coupled to a drain terminal pad, the source lines are commonly coupled to a source terminal pad, and a substrate of the memory array is coupled to a bulk terminal pad. The voltage control device is coupled to the memory array and is configured to change states of the gate terminal pad, the drain terminal pad, the source terminal pad, and the bulk terminal pad during a period of performing a test operation. The test device is coupled to the memory array and is configured to provide multiple output signals according to changes in the states of the gate terminal pad, the drain terminal pad, the source terminal pad, and the bulk terminal pad. The determination device is coupled to the test device and is configured to determine whether a breakdown phenomenon occurs in the memory array and a location where the breakdown phenomenon occurs according to the output signals.

A test method of the disclosure is suitable for the memory array and includes the following steps. States of a gate terminal pad, a drain terminal pad, a source terminal pad, and the bulk terminal pad are changed during a period of performing a test operation. Multiple output signals are provided according to changes in the states of the gate terminal pad, the drain terminal pad, the source terminal pad, and the bulk terminal pad. Whether a breakdown phenomenon occurs in the memory array and a location where the breakdown phenomenon occurs are determined according to the output signals.

Based on the above, the memory test system and the test method thereof of the disclosure can detect the breakdown phenomenon in the memory array through an electrical failure analysis, which not only saves time and cost, but is also suitable for mass production of products.

In order for the features and advantages of the disclosure to be more comprehensible, the following specific embodiments are described in detail in conjunction with the drawings.

### BRIEF DESCRIPTION OF THE DRAWINGS

FIG. 1 is a block schematic diagram of a memory test system according to an embodiment of the disclosure.

FIG. 2 is a structural schematic diagram of a memory cell according to an embodiment of the disclosure.

FIG. 3 is a circuit schematic diagram of an equivalent circuit of a memory cell according to an embodiment of the disclosure.

FIG. 4 is a circuit schematic diagram of a memory test system according to an embodiment of the disclosure.

FIG. 5 is a step flowchart of a test operation according to an embodiment of the disclosure.

FIG. 6 is a step flowchart of a test method according to an embodiment of the disclosure.

### DESCRIPTION OF THE EMBODIMENTS

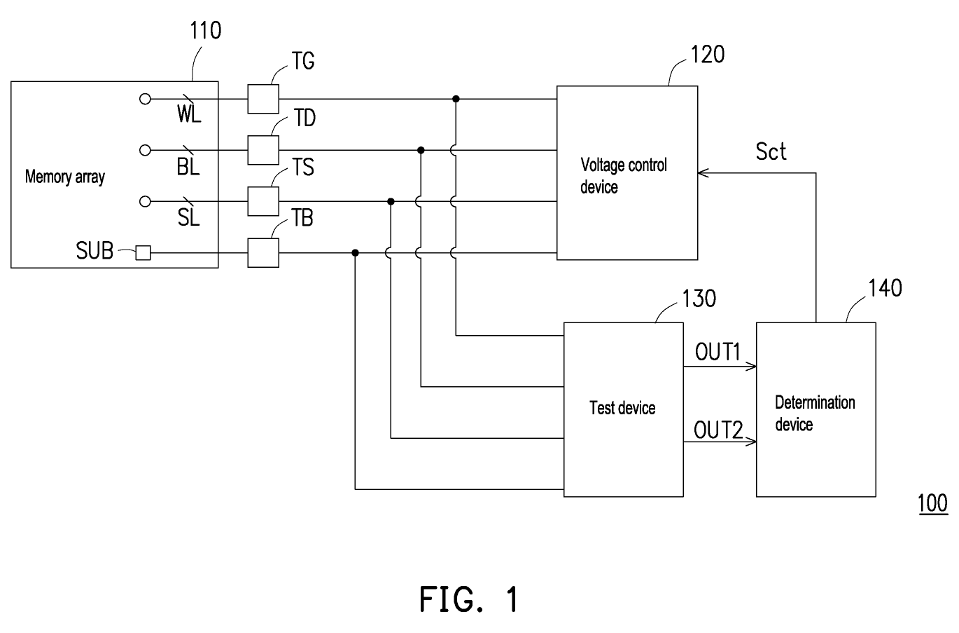

Please refer to FIG. 1. A memory test system 100 includes a memory array 110, a voltage control device 120, a test device 130, and a determination device 140. The memory array 110 is, for example, a non-volatile memory array and may be composed of a NOR flash memory or a NAND flash memory. The memory array 110 has multiple word lines WL, multiple bit lines BL, and multiple source lines SL.

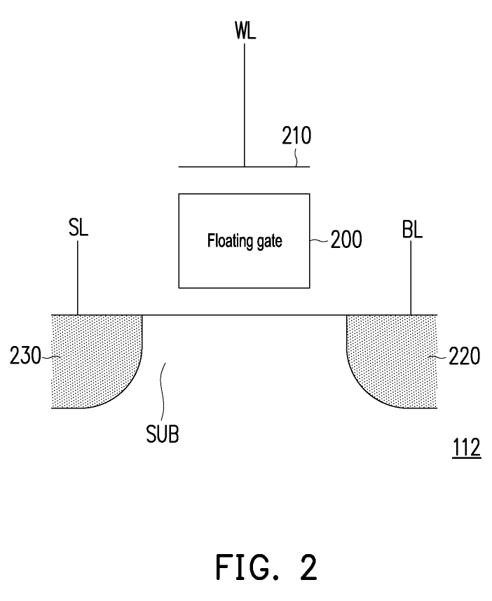

The memory array 110 also includes multiple memory cells 112. As shown in FIG. 2, each memory cell 112 includes a floating gate 200, a control gate 210, a drain 220, a source 230, and a substrate SUB. The control gate 210 is coupled to the corresponding word line WL, the drain 220 is coupled to the corresponding bit line BL, and the source 230 is coupled to the corresponding source line SL.

In FIG. 1, the word lines WL extending from the control gates 210 of the memory cells 112 are commonly coupled to a gate terminal pad TG. The bit lines BL extending from the drains 220 of the memory cells 112 are commonly coupled to a drain terminal pad TD. The source lines SL extending from the sources 230 of the memory cells 112 are commonly coupled to a source terminal pad TS. The substrate SUB of the memory array 110 is coupled to a bulk terminal pad TB.

The voltage control device 120 is coupled to the memory array 110 via the gate terminal pad TG, the drain terminal pad TD, the source terminal pad TS, and the bulk terminal pad TB. The voltage control device 120 includes, for example, a regulator having a charge pump circuit and a switch circuit capable of switching a conductive path. During a period of performing a test operation, the voltage control device 120 may change the states of the gate terminal pad TG, the drain terminal pad TD, the source terminal pad TS, and the bulk terminal pad TB. Specifically, the voltage control device 120 may adjust voltage values respectively applied to the gate terminal pad TG, the drain terminal pad TD, the source terminal pad TS, and the bulk terminal pad TB or switch the gate terminal pad TG, the drain terminal pad TD, the source terminal pad TS, and the bulk terminal pad TB to a floating state according to a control signal Sct output by the determination device 140. During the period of performing the test operation, the voltage control device 120 sequentially applies a test voltage Vt (for example, 5V) to at least one pad among the gate terminal pad TG, the drain terminal pad TD, the source terminal pad TS, and the bulk terminal pad TB, and simultaneously switches the other pads among the gate terminal pad TG, the drain terminal pad TD, the source terminal pad TS, and the bulk terminal pad TB to the floating state.

The test device 130 is also coupled to the memory array 110 via the gate terminal pad TG, the drain terminal pad TD, the source terminal pad TS, and the bulk terminal pad TB. The test device 130 may provide multiple output signals (a first output signal OUT1 and a second output signal OUT2) according to changes in the states of the gate terminal pad TG, the drain terminal pad TD, the source terminal pad TS, and the bulk terminal pad TB. Specifically, during the period of performing the test operation, the test device 130 may provide the first output signal OUT1 and the second output signal OUT2 according to the voltage levels of the gate terminal pad TG, the drain terminal pad TD, the source terminal pad TS, and the bulk terminal pad TB. The timing levels of the first output signal OUT1 and the second output signal OUT2 may indicate whether a breakdown phenomenon occurs in the memory array 110 and a location where the breakdown phenomenon occurs.

The determination device 140 is coupled to the voltage control device 120 and the test device 130. The determination device 140 is implemented, for example, by a state machine, a central processing unit, other programmable general-purpose or specific-purpose microprocessors, digital signal processors, programmable controllers, application-specific integrated circuits, programmable logic devices, other similar devices, or a combination of the devices. The determination device 140 may output the control signal Sct to the voltage control device 120 to control the voltage control device 120, and determine whether the breakdown phenomenon occurs in the memory array 110 and the location where the breakdown phenomenon occurs according to the first output signal OUT1 and the second output signal OUT2 provided by the test device 130.

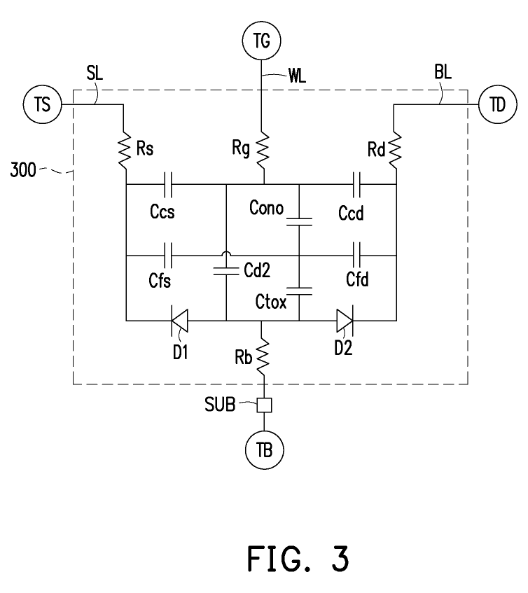

FIG. 3 indicates an equivalent circuit 300 of the memory cell 112 encapsulated by a sidewall oxide layer (that is, a sidewall spacer). The equivalent circuit 300 includes a bulk terminal resistor Rb, a silicon structure capacitor Cd2, a gate terminal resistor Rg, a first sidewall capacitor Ccs, a source terminal resistor Rs, a second sidewall capacitor Ccd, a drain terminal resistor Rd, a tunnel oxide layer capacitor Ctox, a composite layer capacitor Cono, a source capacitor Cfs, a drain capacitor Cfd, a first diode D1, and a second diode D2. A first terminal of the bulk terminal resistor Rb is coupled to the bulk terminal pad TB via the substrate SUB. A first terminal of the silicon structure capacitor Cd2 is coupled to a second terminal of the bulk terminal resistor Rb. A first terminal of the gate terminal resistor Rg is coupled to a second terminal of the silicon structure capacitor Cd2, and a second terminal of the gate terminal resistor Rg is coupled to the gate terminal pad TG via the corresponding word line WL. A first terminal of the first sidewall capacitor Ccs is coupled to the first terminal of the gate terminal resistor Rg. A first terminal of the source terminal resistor Rs is coupled to a second terminal of the first sidewall capacitor Ccs, and a second terminal of the source terminal resistor Rs is coupled to the source terminal pad TS via the corresponding source line SL. A first terminal of the second sidewall capacitor Ccd is coupled to the first terminal of the gate terminal resistor Rg. A first terminal of the drain terminal resistor Rd is coupled to a second terminal of the second sidewall capacitor Ccd, and a second terminal of the drain terminal resistor Rd is coupled to the drain terminal pad TD via the corresponding bit line BL. A first terminal of the tunnel oxide layer capacitor Ctox is coupled to the second terminal of the bulk terminal resistor Rb. A first terminal of the composite layer capacitor Cono is coupled to a second terminal of the tunnel oxide layer capacitor Ctox, and a second terminal of the composite layer capacitor Cono is coupled to the first terminal of the gate terminal resistor Rg. A first terminal of the source capacitor Cfs is coupled to the second terminal of the tunnel oxide layer capacitor Ctox, and a second terminal of the source capacitor Cfs is coupled to the first terminal of the source terminal resistor Rs. A first terminal of the drain capacitor Cfd is coupled to the second terminal of the tunnel oxide layer capacitor Ctox, and a second terminal of the drain capacitor Cfd is coupled to the first terminal of the drain terminal resistor Rd. An anode terminal of the first diode D1 is coupled to the second terminal of the bulk terminal resistor Rb, and a cathode terminal of the first diode D1 is coupled to the first terminal of the source terminal resistor Rs. An anode terminal of the second diode D2 is coupled to the second terminal of the bulk terminal resistor Rb, and a cathode terminal of the second diode D2 is coupled to the first terminal of the drain terminal resistor Rd.

It should be noted that the silicon structure capacitor Cd2 of the embodiment is equivalent to an oxide layer structure between the substrate SUB (that is, the bulk) and the control gate. First, the sidewall capacitor Ccs is equivalent to a sidewall oxide layer of a source side, which may isolate the source from the control gate. The second sidewall capacitor Ccd is equivalent to a sidewall oxide layer of a drain side, which may isolate the drain from the control gate. The disclosure focuses on detecting whether the silicon structure capacitor Cd2, the first sidewall capacitor Ccs, and the second sidewall capacitor Ccd may allow current to pass through, so as to determine whether the breakdown phenomenon occurs in the oxide layer structure between the control gates, the sidewall oxide layer of the source side, and the sidewall oxide layer of the drain side.

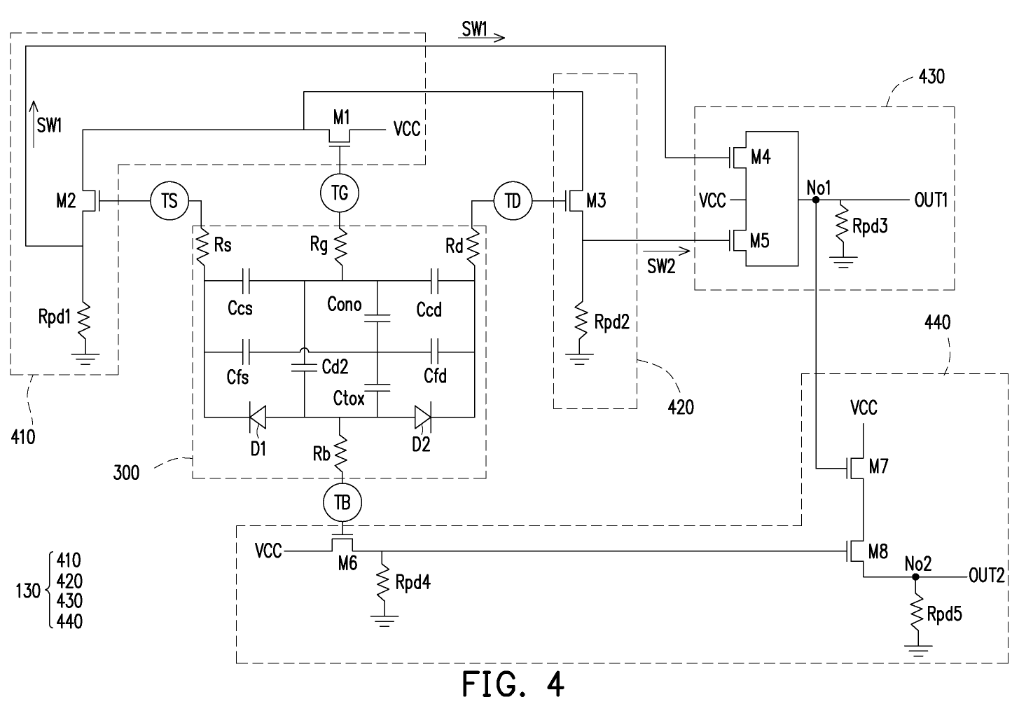

An embodiment is given below to illustrate implementation details of the test device 130. Please refer to FIG. 4. The test device 130 includes a first test circuit 410, a second test circuit 420, a third test circuit 430, and a fourth test circuit 440. The first test circuit 410 is coupled to the gate terminal pad TG and the source terminal pad TS. The first test circuit 410 may output a first switching signal SW1 according to the voltage levels of the gate terminal pad TG and the source terminal pad TS. In detail, the first test circuit 410 includes a first transistor M1, a second transistor M2, and a first pull-down resistor Rpd1. A first terminal of the first transistor M1 receives a supply voltage VCC (for example, 3.3V to 5V), and a control terminal of the first transistor M1 is coupled to the gate terminal pad TG. A first terminal of the second transistor M2 is coupled to a second terminal of the first transistor M1, a control terminal of the second transistor M2 is coupled to the source terminal pad TS, and a second terminal of the second transistor M2 is used to output the first switching signal SW1. A first terminal of the first pull-down resistor Rpd1 is coupled to the second terminal of the second transistor M2, and a second terminal of the first pull-down resistor Rpd1 is grounded.

When the gate terminal pad TG and the source terminal pad TS are both at a first voltage level L1 (for example, a high voltage level), the first transistor M1 and the second transistor M2 are simultaneously conducted, so that the supply voltage VCC is transmitted from the first terminal of the first transistor M1 to the second terminal of the second transistor M2, and the output first switching signal SW1 is converted to the first voltage level L1. When one of the gate terminal pad TG and the source terminal pad TS is at a second voltage level L2 (for example, a low voltage level), the first transistor M1 and the second transistor M2 are not simultaneously conducted, so that the supply voltage VCC cannot be transmitted from the first terminal of the first transistor M1 to the second terminal of the second transistor M2, and the output first switching signal SW1 is converted to the second voltage level L2.

The second test circuit 420 is coupled to the first test circuit 410 and the drain terminal pad TD. The second test circuit 420 may output a second switching signal SW2 according to the voltage levels of the gate terminal pad TG and the drain terminal pad TD. In detail, the second test circuit 420 includes a third transistor M3 and a second pull-down resistor Rpd2. A first terminal of the third transistor M3 is coupled to the second terminal of the first transistor M1, a control terminal of the third transistor M3 is coupled to the drain terminal pad TD, and a second terminal of the third transistor M3 is used to output the second switching signal SW2. A first terminal of the second pull-down resistor Rpd2 is coupled to the second terminal of the third transistor M3, and a second terminal of the second pull-down resistor Rpd2 is grounded.

When the gate terminal pad TG and the drain terminal pad TD are both at the first voltage level L1, the first transistor M1 and the third transistor M3 are simultaneously conducted, so that the supply voltage VCC is transmitted from the first terminal of the first transistor M1 to the second terminal of the third transistor M3, and the output second switching signal SW2 is converted to the first voltage level L1. When one of the gate terminal pad TG and the drain terminal pad TD is at the second voltage level L2, the first transistor M1 and the third transistor M3 are not simultaneously conducted, so that the supply voltage VCC cannot be transmitted from the first terminal of the first transistor M1 to the second terminal of the third transistor M3, and the output second switching signal SW2 is converted to the second voltage level L2.

The third test circuit 430 is coupled to the first test circuit 410 and the second test circuit 420. The third test circuit 430 may receive the first switching signal SW1 and the second switching signal SW2, and output a first output signal OUT1 according to the first switching signal SW1 and the second switching signal SW2. In detail, the third test circuit 430 includes a fourth transistor M4, a fifth transistor M5, and a third pull-down resistor Rpdb. A first terminal of the fourth transistor M4 receives the supply voltage VCC, a control terminal of the fourth transistor M4 receives the first switching signal SW1, and a second terminal of the fourth transistor M4 is coupled to a first output node No1. The first output node No1 is used to output the first output signal OUT1. A first terminal of the fifth transistor M5 receives the supply voltage VCC, a control terminal of the fifth transistor M5 receives the second switching signal SW2, and a second terminal of the fifth transistor M5 is coupled to the first output node No1. A first terminal of the third pull-down resistor Rpd3 is coupled to the first output node No1, and a second terminal of the third pull-down resistor Rpd3 is grounded.

When one of the first switching signal SW1 and the second switching signal SW2 is at the first voltage level L1, the corresponding transistor is conducted, so that the supply voltage VCC is transmitted to the first output node No1, and the output first output signal OUT1 is converted to the first voltage level L1. When the first switching signal SW1 and the second switching signal SW2 are both at the second voltage level L2, the fourth transistor M4 and the fifth transistor M5 are not conducted, so that the supply voltage VCC cannot be transmitted to the first output node No1, and the output first output signal OUT1 is converted to the second voltage level L2.

The fourth test circuit 440 is coupled to the third test circuit 430 and the bulk terminal pad TB. The fourth test circuit 440 may output a second output signal OUT2 according to the voltage levels of the first output signal OUT1 and the bulk terminal pad TB. In detail, the fourth test circuit 440 includes a sixth transistor M6, a fourth pull-down resistor Rpd4, a seventh transistor M7, an eighth transistor M8, and a fifth pull-down resistor Rpd5. A first terminal of the sixth transistor M6 receives the supply voltage VCC, and a control terminal of the sixth transistor M6 is coupled to the bulk terminal pad TB. A first terminal of the fourth pull-down resistor Rpd4 is coupled to a second terminal of the sixth transistor M6, and a second terminal of the fourth pull-down resistor Rpd4 is grounded. A first terminal of the seventh transistor M7 receives the supply voltage VCC, and a control terminal of the seventh transistor M7 is coupled to the first output node No1 to receive the first output signal OUT1. A first terminal of the eighth transistor M8 is coupled to a second terminal of the seventh transistor M7, a control terminal of the eighth transistor M8 is coupled to the second terminal of the sixth transistor M6, and a second terminal of the eighth transistor M8 is coupled to a second output node No2. The second output node No2 is used to output the second output signal OUT2. A first terminal of the fifth pull-down resistor Rpd5 is coupled to the second output node No2, and a second terminal of the fifth pull-down resistor Rpdb is grounded.

When the first output signal OUT1 and the bulk terminal pad TB are both at the first voltage level L1, the sixth transistor M6 is conducted, so that the supply voltage VCC is transmitted to the control terminal of the eighth transistor M8, thereby conducting the eighth transistor M8. The seventh transistor M7 and the eighth transistor M8 are simultaneously conducted, so that the supply voltage VCC is transmitted from the first terminal of the seventh transistor M7 to the second output node No2, and the output second output signal OUT2 is converted to the first voltage level L1. When one of the first output signal OUT1 and the bulk terminal pad TB is at the second voltage level L2, the seventh transistor M7 and the eighth transistor M8 are not simultaneously conducted, so that the supply voltage VCC cannot be transmitted from the first terminal of the seventh transistor M7 to the second output node No2, and the output second output signal OUT2 is converted to the second voltage level L2. In the embodiment, the first to eighth transistors M1 to M8 may be implemented, for example, by N-type metal-oxide-semiconductor field-effect transistors (NMOSFET).

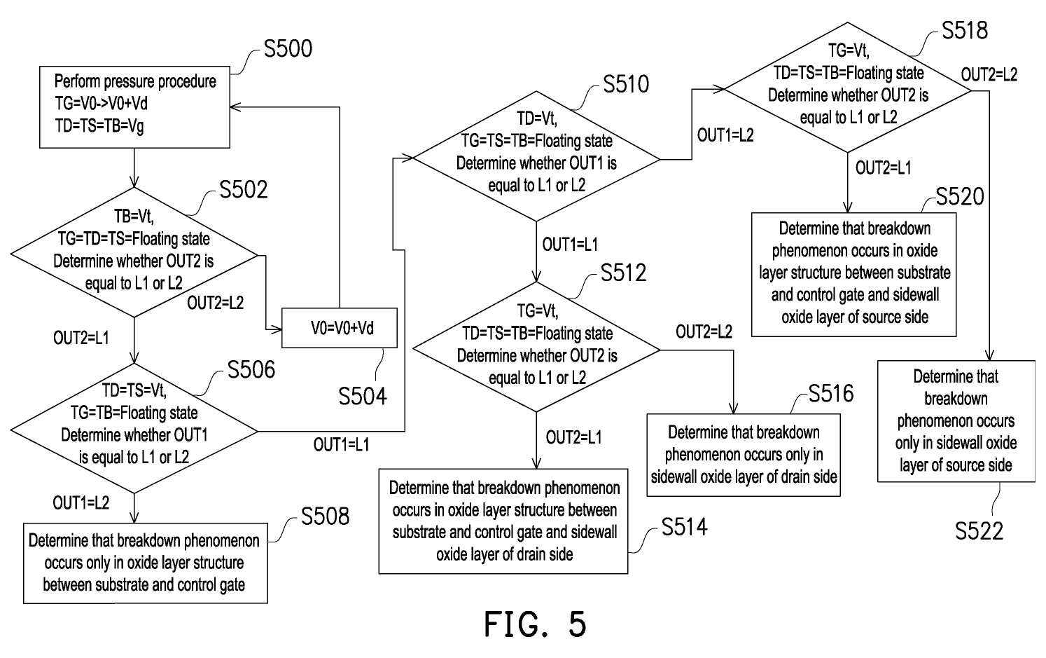

An embodiment is given below to illustrate implementation details of the test operation. Please refer to FIG. 1, FIG. 4, and FIG. 5 together. First, in step S500, the voltage control device 120 adjusts the voltage values respectively applied to the gate terminal pad TG, the drain terminal pad TD, the source terminal pad TS, and the bulk terminal pad TB to perform a pressure procedure. Specifically, during a period of the pressure procedure, the voltage control device 120 applies a ground voltage Vg (for example, 0 volts) to the drain terminal pad TD, the source terminal pad TS, and the bulk terminal pad TB, and gradually increases the voltage value of the gate terminal pad TG from a reference voltage V0 to the reference voltage V0 plus a predetermined voltage Vd (for example, 10 volts).

Next, in step S502, the voltage control device 120 applies the test voltage Vt (for example, 5V) to the bulk terminal pad TB, and simultaneously switches the gate terminal pad TG, the drain terminal pad TD, and the source terminal pad TS to the floating state. The test device 130 may decide the voltage level of the provided second output signal OUT2 according to the voltage levels of the gate terminal pad TG, the drain terminal pad TD, the source terminal pad TS, and the bulk terminal pad TB at this time, and the determination device 140 determines whether the second output signal OUT2 is equal to the first voltage level L1 or the second voltage level L2.

When the second output signal OUT2 is equal to the second voltage level L2 (OUT2=L2) in step S502, it indicates that the silicon structure capacitors Cd2, the first sidewall capacitors Ccs, and the second sidewall capacitors Ccd in the equivalent circuits 300 of all the memory cells 112 do not allow current to pass through. The determination device 140 determines that the breakdown phenomenon does not occur in the memory array 110 at this time, and then in step S504, the voltage control device 120 updates the reference voltage V0 to the original reference voltage V0 plus the predetermined voltage Vd (V0=V0+Vd), and the process returns to step S500 to perform the pressure procedure again. Thus, the voltage control device 120 may repeatedly perform the pressure procedure with the incrementing reference voltage V0 until the second output signal OUT2 is equal to the first voltage level L1. In an embodiment, when the number of times of repeatedly performing the pressure procedure reaches a predetermined threshold, the memory test system 100 of the disclosure automatically ends the test operation.

When the second output signal OUT2 is equal to the first voltage level L1 (OUT2=L1) in step S502, it indicates that at least one of the silicon structure capacitor Cd2, the first sidewall capacitor Ccs, and the second sidewall capacitor Ccd may allow current to pass through. The determination device 140 determines that the breakdown phenomenon occurs in the memory array 110 at this time, and then in step S506, the voltage control device 120 applies the test voltage Vt to the drain terminal pad TD and the source terminal pad TS, and simultaneously switches the gate terminal pad TG and the bulk terminal pad TB to the floating state. The test device 130 may decide the voltage level of the provided first output signal OUT1 according to the voltage levels of the gate terminal pad TG, the drain terminal pad TD, the source terminal pad TS, and the bulk terminal pad TB at this time, and the determination device 140 determines whether the first output signal OUT1 is equal to the first voltage level L1 or the second voltage level L2.

When the first output signal OUT1 is equal to the second voltage level L2 (OUT1=L2) in step S506, it indicates that the first sidewall capacitor Ccs and the second sidewall capacitor Ccd do not allow current to pass through, and the breakdown phenomenon occurs only in the silicon structure capacitor Cd2. Therefore, in step S508, the determination device 140 determines that the breakdown phenomenon occurs only in the oxide layer structure between the substrate SUB (that is, the bulk) and the control gate.

When the first output signal OUT1 is equal to the first voltage level L1 (OUT1=L1) in step S506, it indicates that one of the first sidewall capacitor Ccs and the second sidewall capacitor Ccd may allow current to pass through. Next, in step S510, the voltage control device 120 applies the test voltage Vt to the drain terminal pad TD, and simultaneously switches the gate terminal pad TG, the source terminal pad TS, and the bulk terminal pad TB to the floating state. The test device 130 may decide the voltage level of the provided first output signal OUT1 according to the voltage levels of the gate terminal pad TG, the drain terminal pad TD, the source terminal pad TS, and the bulk terminal pad TB at this time, and the determination device 140 determines whether the first output signal OUT1 is equal to the first voltage level L1 or the second voltage level L2.

When the first output signal OUT1 is equal to the first voltage level L1 (OUT1=L1) in step S510, it indicates that the second sidewall capacitor Ccd may allow current to pass through, and the breakdown phenomenon occurs in the second sidewall capacitor Ccd. Next, in step S512, the voltage control device 120 applies the test voltage Vt to the gate terminal pad TG, and simultaneously switches the drain terminal pad TD, the source terminal pad TS, and the bulk terminal pad TB to the floating state. The test device 130 may decide the voltage level of the provided second output signal OUT2 according to the voltage levels of the gate terminal pad TG, the drain terminal pad TD, the source terminal pad TS, and the bulk terminal pad TB at this time, and the determination device 140 determines whether the second output signal OUT2 is equal to the first voltage level L1 or the second voltage level L2.

When the second output signal OUT2 is equal to the first voltage level L1 (OUT2=L1) in step S512, it indicates that in addition to the second sidewall capacitor Ccd, the silicon structure capacitor Cd2 may also allow current to pass through, and the breakdown phenomenon occurs both in the silicon structure capacitor Cd2 and the second sidewall capacitor Ccd. Therefore, in step S514, the determination device 140 determines that the breakdown phenomenon occurs in the oxide layer structure between the substrate SUB and the control gate and the sidewall oxide layer of the drain side.

When the second output signal OUT2 is equal to the second voltage level L2 (OUT2=L2) in step S512, it indicates that the silicon structure capacitor Cd2 does not allow current to pass through, and the breakdown phenomenon occurs only in the second sidewall capacitor Ccd. Therefore, in step S516, the determination device 140 determines that the breakdown phenomenon occurs only in the sidewall oxide layer of the drain side.

When the first output signal OUT1 is equal to the second voltage level L2 (OUT1=L2) in step S510, it indicates that the first sidewall capacitor Ccs may allow current to pass through, and the breakdown phenomenon occurs in the first sidewall capacitor Ccs. Next, in step S518, the voltage control device 120 applies the test voltage Vt to the gate terminal pad TG, and simultaneously switches the drain terminal pad TD, the source terminal pad TS, and the bulk terminal pad TB to the floating state. The test device 130 may decide the voltage level of the provided second output signal OUT2 according to the voltage levels of the gate terminal pad TG, the drain terminal pad TD, the source terminal pad TS, and the bulk terminal pad TB at this time, and the determination device 140 determines whether the second output signal OUT2 is equal to the first voltage level L1 or the second voltage level L2.

When the second output signal OUT2 is equal to the first voltage level L1 (OUT2=L1) in step S518, it indicates that in addition to the first sidewall capacitor Ccs, the silicon structure capacitor Cd2 may also allow current to pass through, and the breakdown phenomenon occurs both in the silicon structure capacitor Cd2 and the first sidewall capacitor Ccs. Therefore, in step S520, the determination device 140 determines that the breakdown phenomenon occurs in the oxide layer structure between the substrate SUB and the control gate and the sidewall oxide layer of the source side.

When the second output signal OUT2 is equal to the second voltage level L2 (OUT2=L2) in step S518, it indicates that the silicon structure capacitor Cd2 does not allow current to pass through, and the breakdown phenomenon occurs only in the first sidewall capacitor Ccs. Therefore, in step S522, the determination device 140 determines that the breakdown phenomenon occurs only in the sidewall oxide layer of the source side.

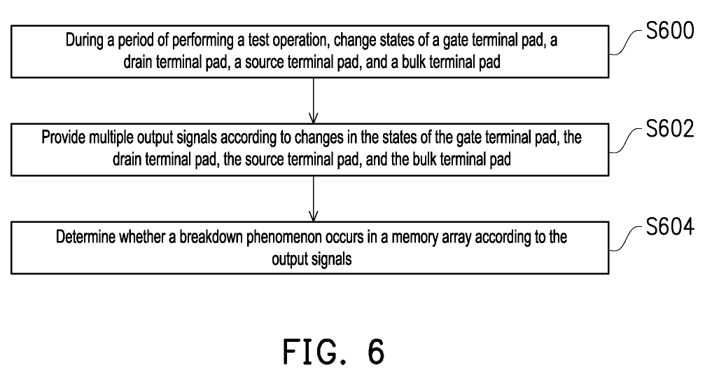

Please refer to FIG. 6. A test method of the embodiment includes the following steps. During a period of performing a test operation, states of a gate terminal pad, a drain terminal pad, a source terminal pad, and a bulk terminal pad are changed (step S600). Multiple output signals are provided according to changes in the states of the gate terminal pad, the drain terminal pad, the source terminal pad, and the bulk terminal pad (step S602). Whether a breakdown phenomenon occurs in a memory array is determined according to the output signals (step S604). Reference may be made to the embodiments of FIG. 1 to FIG. 5 for implementation details of steps S600, S602, and S604 above, which will not be described in detail herein.

In summary, the memory test system and the test method thereof of the disclosure can detect the breakdown phenomenon in the memory array and the location where the breakdown phenomenon occurs through an electrical failure analysis, which not only saves time and cost, but is also suitable for mass production of products.

What is claimed is:

1. A memory test system, comprising:
a memory array, having a plurality of word lines, a plurality of bit lines, and a plurality of source lines, wherein the word lines are commonly coupled to a gate terminal pad, the bit lines are commonly coupled to a drain terminal pad, the source lines are commonly coupled to a source terminal pad, and a substrate of the memory array is coupled to a bulk terminal pad;
a voltage control device, coupled to the memory array and configured to change states of the gate terminal pad, the drain terminal pad, the source terminal pad, and the bulk terminal pad during a period of performing a test operation;
a test device, coupled to the memory array and configured to provide a plurality of output signals according to changes in the states of the gate terminal pad, the drain terminal pad, the source terminal pad, and the bulk terminal pad; and
a determination device, coupled to the test device and configured to determine whether a breakdown phenomenon occurs in the memory array and a location where the breakdown phenomenon occurs according to the output signals.

2. The memory test system according to claim 1, wherein the determination device is coupled to the voltage control device, and the voltage control device adjusts voltage values respectively applied to the gate terminal pad, the drain terminal pad, the source terminal pad, and the bulk terminal pad or switches the gate terminal pad, the drain terminal pad, the source terminal pad, and the bulk terminal pad to a floating state according to a control signal output by the determination device.

3. The memory test system according to claim 1, wherein during the period of performing the test operation, the voltage control device applies a test voltage to at least one of the gate terminal pad, the drain terminal pad, the source terminal pad, and the bulk terminal pad, and simultaneously switches others of the gate terminal pad, the drain terminal pad, the source terminal pad, and the bulk terminal pad to a floating state.

4. The memory test system according to claim 1, wherein during the period of performing the test operation, the test device provides the output signals according to voltage levels of the gate terminal pad, the drain terminal pad, the source terminal pad, and the bulk terminal pad.

5. The memory test system according to claim 4, wherein timing levels of the output signals indicate whether the breakdown phenomenon occurs in the memory array and the location where the breakdown phenomenon occurs.

6. The memory test system according to claim 1, wherein the memory array comprises a plurality of memory cells, and an equivalent circuit of each of the memory cells comprises:
a bulk terminal resistor, having a first terminal coupled to the bulk terminal pad via the substrate;
a silicon structure capacitor, having a first terminal coupled to a second terminal of the bulk terminal resistor;
a gate terminal resistor, having a first terminal coupled to a second terminal of the silicon structure capacitor and a second terminal coupled to the gate terminal pad via the corresponding word line;
a first sidewall capacitor, having a first terminal coupled to a first terminal of the gate terminal resistor;
a source terminal resistor, having a first terminal coupled to a second terminal of the first sidewall capacitor and a second terminal coupled to the source terminal pad via the corresponding source line;
a second sidewall capacitor, having a first terminal coupled to the first terminal of the gate terminal resistor; and
a drain terminal resistor, having a first terminal coupled to a second terminal of the second sidewall capacitor and a second terminal coupled to the drain terminal pad via the corresponding bit line.

7. The memory test system according to claim 6, wherein the equivalent circuit further comprises:
a tunnel oxide layer capacitor, having a first terminal coupled to the second terminal of the bulk terminal resistor;
a composite layer capacitor, having a first terminal coupled to a second terminal of the tunnel oxide layer capacitor and a second terminal coupled to the first terminal of the gate terminal resistor;
a source capacitor, having a first terminal coupled to the second terminal of the tunnel oxide layer capacitor and a second terminal coupled to the first terminal of the source terminal resistor;
a drain capacitor, having a first terminal coupled to the second terminal of the tunnel oxide layer capacitor and a second terminal coupled to the first terminal of the drain terminal resistor;
a first diode, having an anode terminal coupled to the second terminal of the bulk terminal resistor and a cathode terminal coupled to the first terminal of the source terminal resistor; and
a second diode, having an anode terminal coupled to the second terminal of the bulk terminal resistor and a cathode terminal coupled to the first terminal of the drain terminal resistor.

8. The memory test system according to claim 1, wherein the output signals comprise a first output signal and a second output signal, and the test device comprises:
a first test circuit, coupled to the gate terminal pad and the source terminal pad, and configured to output a first switching signal according to voltage levels of the gate terminal pad and the source terminal pad;
a second test circuit, coupled to the first test circuit and the drain terminal pad, and configured to output a second switching signal according to voltage levels of the gate terminal pad and the drain terminal pad;
a third test circuit, coupled to the first test circuit and the second test circuit, and configured to receive the first switching signal and the second switching signal, and output the first output signal according to the first switching signal and the second switching signal; and
a fourth test circuit, coupled to the third test circuit and the bulk terminal pad, and configured to output the second output signal according to voltage levels of the first output signal and the bulk terminal pad.

9. The memory test system according to claim 8, wherein the first test circuit comprises:
a first transistor, having a first terminal receiving a supply voltage and a control terminal coupled to the gate terminal pad;
a second transistor, having a first terminal coupled to a second terminal of the first transistor, a control terminal coupled to the source terminal pad, and a second terminal used to output the first switching signal; and
a first pull-down resistor, having a first terminal coupled to the second terminal of the second transistor and a second terminal grounded.

10. The memory test system according to claim 9, wherein the second test circuit comprises:
a third transistor, having a first terminal coupled to the second terminal of the first transistor, a control terminal coupled to the drain terminal pad, and a second terminal used to output the second switching signal; and
a second pull-down resistor, having a first terminal coupled to the second terminal of the third transistor and a second terminal grounded.

11. The memory test system according to claim 8, wherein the third test circuit comprises:
a fourth transistor, having a first terminal receiving a supply voltage, a control terminal receiving the first switching signal, and a second terminal coupled to a first output node, wherein the first output node is used to output the first output signal;
a fifth transistor, having a first terminal receiving the supply voltage, a control terminal receiving the second switching signal, and a second terminal coupled to the first output node; and
a third pull-down resistor, having a first terminal coupled to the first output node and a second terminal grounded.

12. The memory test system according to claim 11, wherein the fourth test circuit comprises:
a sixth transistor, having a first terminal receiving the supply voltage and a control terminal coupled to the bulk terminal pad;
a fourth pull-down resistor, having a first terminal coupled to a second terminal of the sixth transistor and a second terminal grounded;
a seventh transistor, having a first terminal receiving the supply voltage and a control terminal coupled to the first output node to receive the first output signal;
an eighth transistor, having a first terminal coupled to a second terminal of the seventh transistor, a control terminal coupled to the second terminal of the sixth transistor, and a second terminal coupled to a second output node, wherein the second output node is used to output the second output signal; and
a fifth pull-down resistor, having a first terminal coupled to the second output node and a second terminal grounded.

13. The memory test system according to claim 1, wherein the output signals comprise a first output signal and a second output signal, the voltage control device applies a ground voltage to the drain terminal pad, the source terminal pad, and the bulk terminal pad, and gradually increases a voltage value of the gate terminal pad from a reference voltage to the reference voltage plus a predetermined voltage to perform a pressure procedure, wherein
after performing the pressure procedure, the voltage control device applies a test voltage to the bulk terminal pad, and simultaneously switches the gate terminal pad, the drain terminal pad, and the source terminal pad to a floating state, and the determination device determines whether the second output signal is equal to a first voltage level or a second voltage level, wherein
when the second output signal is equal to the second voltage level, the determination device determines that the breakdown phenomenon does not occur in the memory array,
when the second output signal is equal to the first voltage level, the determination device determines that the breakdown phenomenon occurs in the memory array.

14. The memory test system according to claim 13, wherein when the determination device determines that the breakdown phenomenon does not occur in the memory array, the voltage control device updates the reference voltage to the original reference voltage plus a predetermined voltage to perform the pressure procedure again.

15. The memory test system according to claim 13, wherein when the determination device determines that the breakdown phenomenon occurs in the memory array, the voltage control device applies the test voltage to the drain terminal pad and the source terminal pad, and simultaneously switches the gate terminal pad and the bulk terminal pad to the floating state, and the determination device determines whether the first output signal is equal to the first voltage level or the second voltage level, wherein
when the first output signal is equal to the second voltage level, the determination device determines that the breakdown phenomenon occurs only in an oxide layer structure between the substrate and a control gate in the memory array.

16. The memory test system according to claim 15, wherein when the first output signal is equal to the first voltage level, the voltage control device applies the test voltage to the drain terminal pad, and simultaneously switches the gate terminal pad, the source terminal pad, and the bulk terminal pad to the floating state, the determination device determines whether the first output signal is equal to the first voltage level or the second voltage level, the voltage control device then applies the test voltage to the gate terminal pad, and simultaneously switches the drain terminal pad, the source terminal pad, and the bulk terminal pad to the floating state, and the determination device determines whether the second output signal is equal to the first voltage level or the second voltage level, wherein
when the first output signal and the second output signal are equal to the first voltage level, the determination device determines that the breakdown phenomenon occurs in the oxide layer structure between the substrate and the control gate and a sidewall oxide layer of a drain side in the memory array,
when the first output signal is equal to the first voltage level and the second output signal is equal to the second voltage level, the determination device determines that the breakdown phenomenon occurs only in the sidewall oxide layer of the drain side in the memory array,
when the first output signal is equal to the second voltage level and the second output signal is equal to the first voltage level, the determination device determines that the breakdown phenomenon occurs in the oxide layer structure between the substrate and the control gate and a sidewall oxide layer of a source side in the memory array,
when the first output signal and the second output signal are equal to the second voltage level, the determination device determines that the breakdown phenomenon occurs only in the sidewall oxide layer of the source side in the memory array.

17. The memory test system according to claim 15, wherein when the first output signal is equal to the first voltage level, the voltage control device applies the test voltage to the drain terminal pad, and simultaneously switches the gate terminal pad, the source terminal pad, and the bulk terminal pad to the floating state, and the determination device determines whether the first output signal is equal to the first voltage level or the second voltage level, wherein
when the first output signal is equal to the first voltage level, the determination device determines that the breakdown phenomenon occurs in a sidewall oxide layer of a drain side in the memory array.

18. The memory test system according to claim 17, wherein the voltage control device then applies the test voltage to the gate terminal pad, and simultaneously switches the drain terminal pad, the source terminal pad, and the bulk terminal pad to the floating state, and the determination device determines whether the second output signal is equal to the first voltage level or the second voltage level, wherein
when the first output signal and the second output signal are equal to the first voltage level, the determination device determines that the breakdown phenomenon occurs in the oxide layer structure between the substrate and the control gate and the sidewall oxide layer of the drain side in the memory array,
when the first output signal is equal to the first voltage level and the second output signal is equal to the second voltage level, the determination device determines that the breakdown phenomenon occurs only in the sidewall oxide layer of the drain side in the memory array.

19. The memory test system according to claim 17, wherein the voltage control device then applies the test voltage to the gate terminal pad, and simultaneously switches the drain terminal pad, the source terminal pad, and the bulk terminal pad to the floating state, and the determination device determines whether the second output signal is equal to the first voltage level or the second voltage level, wherein
when the first output signal is equal to the second voltage level and the second output signal is equal to the first voltage level, the determination device determines that the breakdown phenomenon occurs in the oxide layer structure between the substrate and the control gate and a sidewall oxide layer of a source side in the memory array,
when the first output signal and the second output signal are equal to the second voltage level, the determination device determines that the breakdown phenomenon occurs only in the sidewall oxide layer of the source side in the memory array.

20. A test method, suitable for a memory array, wherein the memory array has a plurality of word lines, a plurality of bit lines, and a plurality of source lines, wherein the word lines are commonly coupled to a gate terminal pad, the bit lines are commonly coupled to a drain terminal pad, the source lines are commonly coupled to a source terminal pad, and a substrate of the memory array is coupled to a bulk terminal pad, the test method comprising:
changing states of the gate terminal pad, the drain terminal pad, the source terminal pad, and the bulk terminal pad during a period of performing a test operation;
providing a plurality of output signals according to changes in the states of the gate terminal pad, the drain terminal pad, the source terminal pad, and the bulk terminal pad; and
determining whether a breakdown phenomenon occurs in the memory array and a location where the breakdown phenomenon occurs according to the output signals.
